(19) United States
(12) Patent Application Publication
(10) Pub. No.: US 2023/0063200 A1
(43) Pub. Date: Mar. 2, 2023

(54) SIDEWALL PROTECTED IMAGE SENSOR PACKAGE

(71) Applicant: SEMICONDUCTOR COMPONENTS INDUSTRIES, LLC, Phoenix, AZ (US)

(72) Inventors: Weng-Jin WU, Hsinchu City (TW); Yusheng LIN, Phoenix, AZ (US)

(73) Assignee: SEMICONDUCTOR COMPONENTS INDUSTRIES, LLC, Phoenix, AZ (US)

(21) Appl. No.: 17/822,405

(22) Filed: Aug. 25, 2022

Related U.S. Application Data
(60) Provisional application No. 63/260,701, filed on Aug. 30, 2021.

(51) Int. Cl. H01L 27/146; H01L 23/00

(52) U.S. Cl. CPC H01L 27/14618; H01L 24/20; H01L 27/14683; H01L 24/19; H01L 27/14636; H01L 2224/214; H01L 2224/19

(57) ABSTRACT

A method includes disposing a sheet of glass on a front side of a semiconductor substrate that includes at least one image sensor die, attaching the sheet of glass to the at least one image sensor die by a bead of adhesive material disposed on an edge of the at least one image sensor die, and sawing the semiconductor substrate from a back side to form a trench along a side of the at least one image sensor die. The trench extends through a thickness of the semiconductor substrate and through a part of a thickness of the sheet of glass. The method further includes filling the trench with a molding material to form a layer of molding material on a sidewall of the at least one image sensor die, and singulating the semiconductor substrate to isolate an individual image sensor package enclosing the at least one image sensor die.

### RELATED APPLICATION

This application claims priority to, and the benefit of, U.S. Provisional Patent Application No. 63/260,701, filed Aug. 30, 2021, which is incorporated by reference in its entirety herein.

### TECHNICAL FIELD

This description relates to packaging of semiconductor image sensors.

### BACKGROUND

Digital image sensors (e.g., a complementary metal-oxide-semiconductor image sensor (CIS) or a charge-coupled device (CCD)) are typically packaged in an integrated circuit (IC) package (i.e., a ceramic ball grid array package (CBGA) or a plastic ball grid array (PB GA) package along with a glass cover placed over the image sensor die. With newer applications (e.g., automotive applications such as advanced driver assistance systems (ADAS) and autonomous driving (AD) systems) need other circuitry (e.g., image signal processor (ISP) or ASIC die) to be included in the same IC package as the CIS die for improved imaging performance. The other circuitry (e.g., image signal processor (ISP) or ASIC die) can be placed underneath the image sensor die, which has the glass cover placed over it.

### SUMMARY

In a general aspect, a package includes an assembly of an image sensor die and a glass cover attached to the image sensor die. The glass cover is disposed above an optically active area on a front side of the image sensor die. The package further includes a layer of molding material disposed on a sidewall of the assembly of the image sensor die and the glass cover. The layer of molding material hermetically seals the assembly of the image sensor die and the glass cover.

In a general aspect, a package includes an image sensor die disposed above the image sensor die. At least a top layer of the glass cover has a width greater than a width of the image sensor die. The glass cover is attached to the image sensor die by a bead of adhesive material placed on an edge of the image sensor die. The package further includes a layer of molding material disposed on a sidewall of the image sensor die. The layer of molding material hermetically seals the image sensor die and the glass cover.

In a general aspect, a method includes disposing at least one image sensor die-glass cover assembly on a carrier, and disposing a layer of a molding material on at least a sidewall of the at least one image sensor die-glass cover assembly placed with the glass cover face down on the carrier to form a molded packages structure on the carrier. The method further includes removing the carrier, and singulating the molded packages structure to isolate an individual hermitically sealed image sensor package.

In a general aspect, a method includes disposing a sheet of glass on a front side of a semiconductor substrate that includes at least one image sensor die. The method further includes attaching the sheet of glass to the at least one image sensor die by a bead of adhesive material disposed on an edge of the at least one image sensor die, and sawing the semiconductor substrate from a back side to form a trench along a side of the at least one image sensor die. The trench extends through a thickness of the semiconductor substrate and at most only through a part of a thickness of the sheet of glass. The method further includes filling the trench with a molding material to form a layer of molding material on a sidewall of the at least one image sensor die, and singulating the semiconductor substrate to isolate an individual image sensor package enclosing the at least one image sensor die.

The details of one or more implementations are set forth in the accompanying drawings and the description below. Other features will be apparent from the description and drawings, and from the claims.

### BRIEF DESCRIPTION OF THE DRAWINGS

FIGS. 1A through 5B example image sensor packages.

FIGS. 6A through 6D illustrate individual image sensor die-glass cover assemblies that may be singulated from a molded semiconductor substrate or mold carrier.

FIG. 7 illustrates an example method for fabricating a chip scale image sensor package.

FIGS. 8A through 8H illustrate cross-sectional views of an image sensor package at different stages of construction.

FIGS. 9A and 9B illustrate cross-sectional views of an image sensor package at different stages of construction.

FIGS. 10A through 10I illustrate cross-sectional views of an image sensor package at different stages of construction.

FIGS. 11A through 11J illustrate cross-sectional views of an image sensor package at different stages of construction.

FIG. 12 illustrates an example method for fabricating chip scale image sensor packages.

FIGS. 13A through 13H illustrate cross-sectional views of an image sensor package at different stages of construction.

### DETAILED DESCRIPTION

An image sensor (e.g., a complementary metal-oxide semiconductor (CMOS) pixel sensor) fabricated on a semiconductor die includes an optically active surface area with an array of pixels responsible for converting a light and color spectrum into electrical signals. The optically active surface area of an image sensor may also, for example, a micro lens array to help funnel incoming light into each pixel (thereby increasing the sensitivity of the image sensor) and/or include a color filter array (CFA) (i.e., a mosaic of tiny color filters coupled to the pixel sensors to capture color information).

This disclosure describes hermetically sealing chip-scale packages (CSPs) of image sensor dies, and methods for batch fabricating the hermetically sealed CSPs using wafer level processing steps.

CSP is a category of an integrated circuit package, which is surface mountable (in other words, a single-die, direct surface mountable package). Bare die such as integrated circuits may be assembled in plastic or ceramic carriers whose dimensions are slightly larger than the chip. Based on some industry standards (e.g., the IPC/JEDEC JEDEC Solid State Technology Association J-STD-012) the CSP area is not more than 1.5 times the die area or the linear dimensions of the CSP are no more than 1.2 times the width or length of the die. CSPs are increasingly used in the industry for integrated circuit packaging, for example, because of the advantages of small size and surface mountable technology. The CSPs are used, for example, in diverse electronic products such as cell phones, smart devices, laptops, digital cameras, etc.

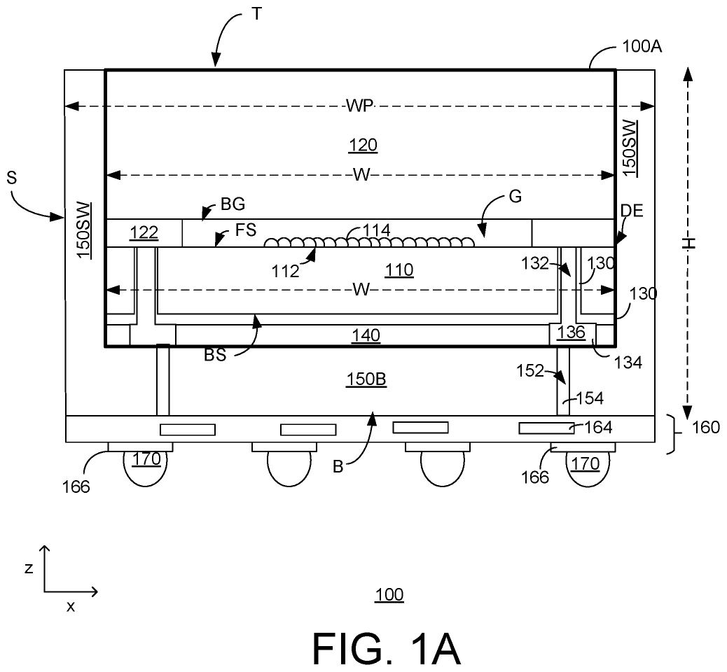

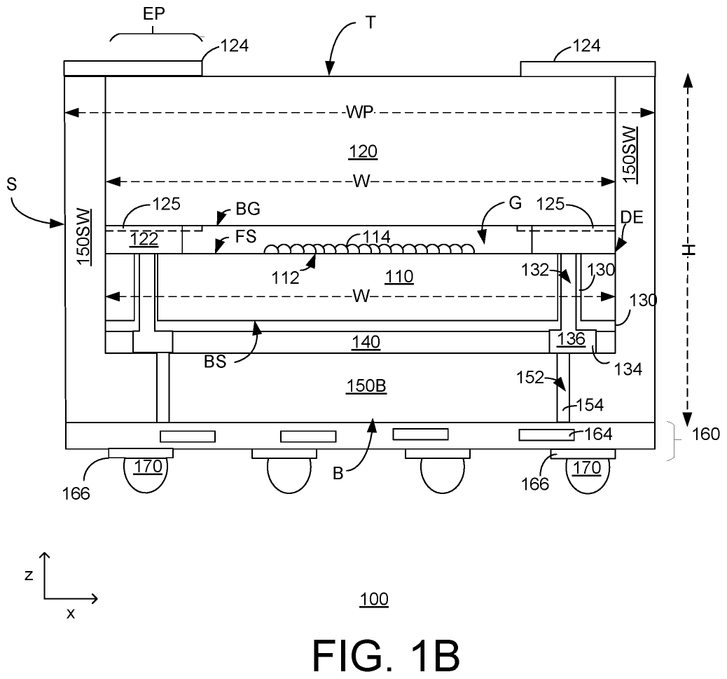

FIGS. 1A through 5B show, in cross-sectional views, features of image sensor CSPs that are at least partially hermetically sealed by layers of molding material (e.g., a resin, an epoxy, an epoxy molding compound (EMC), etc.) disposed on sidewalls of the package, in accordance with the principles of the present disclosures.

FIG. 1A shows a cross-sectional view of an example image sensor package 100.

Image sensor package 100 can be a molded CSP package fabricated by wafer level processes. Image sensor package 100 includes, for example, an image sensor die 110 with an optically active sensor area (e.g., OASA 112) disposed on a top surface FS of the image sensor die. OASA 112 may include a layer of pixels (not shown), a layer of color filters (not shown) and a layer of micro lenses 114 disposed on top surface FS of image sensor die 110. Image sensor die 110 may have, for example, a width W (e.g., in the x direction).

An optically transparent glass cover (e.g., glass 120) overlays the image sensor die. Glass 120 may have a width that is the same (or about the same) as the width of image sensor die 110, i.e., a width W (in the x direction).

Glass 120 may be attached to image sensor die 110, for example, by a bead of a dam or adhesive material (e.g., dam 122)) disposed on edges (e.g., edge DE) of the image sensor die. The glass cover provides a hard cleanable surface as the top surface of the image sensor die and can physically shield the delicate image sensor surface (e.g., the optically active surface area) from physical damage (caused, e.g., by dirt; dust; fingerprints; grease; smudges, etc.). In example implementations, the glass cover is positioned above the image sensor surface with an air gap G interposed between a bottom surface of the glass cover and the optically active surface area (i.e., above the sensor pixels, CFA and micro lens layers). The presence of the air gap can mitigate or reduce image-degrading optical phenomena (e.g., halo flares) that may be caused by reflected light being scattered back on to the optically active surface area.

A passivation layer (e.g., silicon oxide or nitride, or other dielectric) (e.g., passivation layer 130) may be disposed on a bottom surface (BS) of image sensor die 110. Further, a first redistribution layer (RDL 140) (a signal redistribution layer) may be disposed on passivation layer 130. RDL 140 may be made of insulating material, for example, a dam material (e.g., an epoxy or resin) and include conductive traces or pads (e.g., contact pads 136) of a back side metallization layer of the image sensor die. Through semiconductor vias (e.g., TSV 132) may be etched through image sensor die 110 and passivation layer 130 into RDL 140 to provide electrical connections between the front side (e.g., top surface FS) of image sensor die 110 and the back side (e.g., bottom surface BS) of the die. In the example shown in FIG. 1A, a conductive material (e.g., a metal 134) may be filled in TSV 132 to provide electrical connections to the front side (e.g., top surface FS) of image sensor die 110 from the back side (e.g., bottom surface BS) of image sensor die 110. The conductive material (e.g., metal 134) filled in TSV 132 may connect the front side (e.g., top surface FS) of image sensor die 110 to the traces (e.g., contact pads 136) in RDL 140 disposed on the back side (e.g., bottom surface BS) of image sensor die 110.

Further, in image sensor package 100, a molding compound may be disposed on a bottom side B and on four vertical sides S of the image sensor die-glass cover assembly to form a bottom mold layer (e.g., mold layer 150B) and four sidewall mold layers (e.g., sidewall mold layer 150SW). The bottom mold layer (e.g., mold layer 150B) and the four sidewall mold layers (e.g., sidewall mold layer 150SW) may hermetically seal (e.g., moisture proof or waterproof) the image sensor die-glass cover assembly (image sensor die 110 and glass 120) from the bottom side and from the four vertical sides of the package. The sixth side of the package is the top surface (e.g., top surface T) of glass 120 used in the image sensor die-glass cover assembly.

The combined structure of the image sensor die, the glass cover, and the first redistribution layer may be referred to as the “image sensor die-glass cover assembly” (e.g., image sensor die-glass cover assembly 100A) of the package herein.

As shown in FIG. 1A, bottom mold layer (e.g., mold layer 150B) may be formed in an x-y plane at bottom B of the package and the four sidewall mold layers (e.g., sidewall mold layer 150SW) may be vertical sidewalls of the package extending in the z direction from the x-y plane. The four sidewall mold layers (e.g., sidewall mold layer 150SW) may have a height H (in the z direction). Image sensor package 100 including the four sidewall mold layers (e.g., mold layer 150SW) may have a width WP (in the x direction). WP may be greater that the width W of the image sensor die by up to about 20% to maintain a categorization of image sensor package 100 as a CSP under an industry standard (e.g., the IPC/JEDEC JEDEC Solid State Technology Association standard: J-STD-012).

The bottom mold layer (e.g., bottom mold layer 150B) and four sidewall mold layers (e.g., sidewall mold layer 150SW) may block stray light from entering the image sensor die-glass cover assembly from the sides and the bottom of the assembly (e.g., light passing through the semiconductor material of the image sensor die or light incident through sides of glass cover (e.g., glass 120) on airgap G).

The bottom mold layer (e.g., bottom mold layer 150B) and four sidewall mold layers (e.g., sidewall mold layer 150SW) may hermetically seal the image sensor die-glass cover assembly and block ingress of moisture into the image sensor die-glass cover assembly.

Further, in image sensor package 100, a second redistribution layer (RDL 160) (a signal redistribution layer) may be disposed on the bottom B of the bottom mold layer (e.g., mold layer 150B). RDL 160 may be made of insulating material (e.g., silicon oxide or nitride, or epoxy). RDL 160 may include internal metallization layers (e.g., conductive traces or pads 164) and external input/output pads (e.g., pads 166) for electrical connections to the image sensor die in the package. The internal metallization layers (e.g., conductive traces or pads 164) in RDL 160 may be electrically connected to contact pads 136 (in the first redistribution layer (RDL 140) on the back side (e.g., bottom surface BS) of image sensor die 110) by conductive material 154 filled in through-mold vias (e.g., TMV 152) that extend through the bottom mold layer (e.g., mold layer 150B).

In example implementations, solder bumps 170 may be disposed on external input/output pads (e.g., pads 166) of the package so that the image sensor package 100 is surface mountable (e.g., on a printed circuit board) in circuit applications.

It is noted that in the example image sensor package 100 shown in FIG. 1A, the top surface (e.g., top surface T) of glass 120 can be a clear glass surface extending over a full width (e.g., width W) of the glass cover. In some implementations, edge portions of the top surface (e.g., top surface T) of glass 120 and/or edge portions of the bottom surface (e.g., bottom surface BG) of glass 120 may be coupled to (e.g., coated with) a light blocking material (e.g., a molding material, a black paint, a non-transparent or opaque, epoxy, resin, or polymer, etc.), for example, to prevent light incident at side angles from reaching the optically active sensor area (e.g., OASA 112) disposed on top surface FS of the image sensor die in the package. In some implementations, the bead of the dam or adhesive material (e.g., dam 122)) disposed on edges (e.g., edge DE) of the image sensor die to attach glass 120 may function as a light blocking material coupled to the bottom surface BG of the glass cover to prevent light incident at side angles from reaching the optically active sensor area (e.g., OASA 112).

FIG. 1B shows, for example, image sensor package 100 with a light blocking material (e.g., light blocking material 124) coupled to edge portions (e.g., edge portion EP) of the top surface (e.g., top surface T) of glass 120. In some implementations, edge portions of the bottom surface (e.g., bottom surface BG) of glass 120 may be coupled to a light blocking material (e.g., light blocking material 125) (e.g., a molding material, a black paint, a non-transparent or opaque, epoxy, resin, or polymer, etc.) to prevent light incident at side angles from reaching the optically active sensor area (e.g., OASA 112) disposed on top surface FS of the image sensor die in the package. Light blocking material 125 may be a same material as, or another material co-disposed with, the bead of the dam or adhesive material (e.g., dam 122)) disposed on edges (e.g., edge DE) of the image sensor die 110 to attach glass 120.

In some implementations of the package (e.g., image sensor package 100 shown in FIGS. 1A and 1B) may not include a second redistribution layer (e.g., RDL 160) disposed on the bottom mold layer (e.g., mold layer 150B) for back side electrical connections to image sensor die enclosed in the package. Instead in these implementations, external input/output pads (e.g., pads 166) of the package may be disposed directly on the bottom of the bottom mold layer (e.g., mold layer 150B).

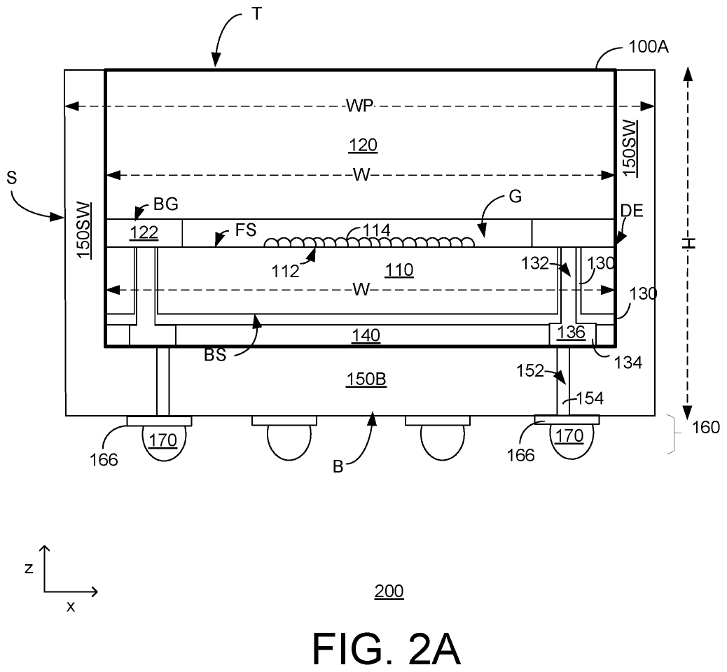

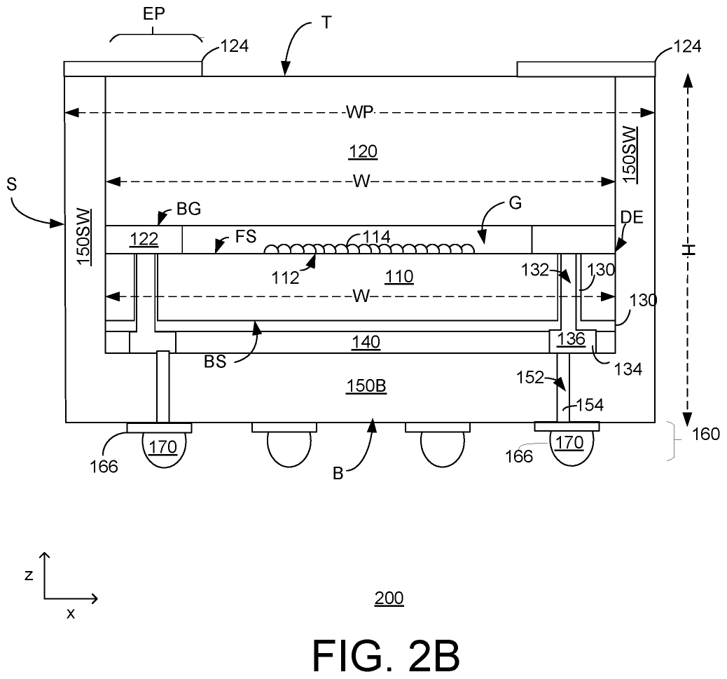

FIGS. 2A and 2B show, for example, cross-sectional view of an image sensor package 200 having external input/output pads of the package disposed directly on the bottom mold layer.

Image sensor package 200 shown in FIG. 2A, like image sensor package 100 shown in FIG. 1A, includes an image sensor die-glass cover assembly (e.g., image sensor die-glass cover assembly 100A) that is hermetically sealed by a bottom mold layer and four sidewall mold layers (e.g., bottom mold layer 150B, sidewall mold layer 150SW). In image sensor package 200, external input/output pads (e.g., pads 166) of the package are disposed directly on the bottom mold layer (e.g., mold layer 150B). Solder bumps 170 are disposed on the external input/output pads (e.g., pads 166) on mold layer 150B of the package so that the image sensor package 200 is surface mountable (e.g., on a printed circuit board) in circuit applications.

Image sensor package 200 shown in FIG. 2A, like image sensor package 100 shown in FIG. 1A, has the top surface (e.g., top surface T) of glass 120 that is a clear glass surface extending over a full width (e.g., width W) of the glass cover.

FIG. 2B shows image sensor package 200, like image sensor package 100 shown in FIG. 1B, with a light blocking material (e.g., light blocking material 124) disposed on edge portions (e.g., edge portion EP) of the top surface (e.g., top surface T) of glass 120.

In some implementations, an image sensor package may be hermetically sealed only by the four sidewall mold layers (e.g., sidewall mold layer 150SW). There may be no mold layer (e.g., the mold layer 150B, FIGS. 2A and 2B) disposed on the bottom side of the package (i.e., on the first redistribution layer (RDL 140) on the bottom surface BS of image sensor die 110, FIGS. 2A and 2B).

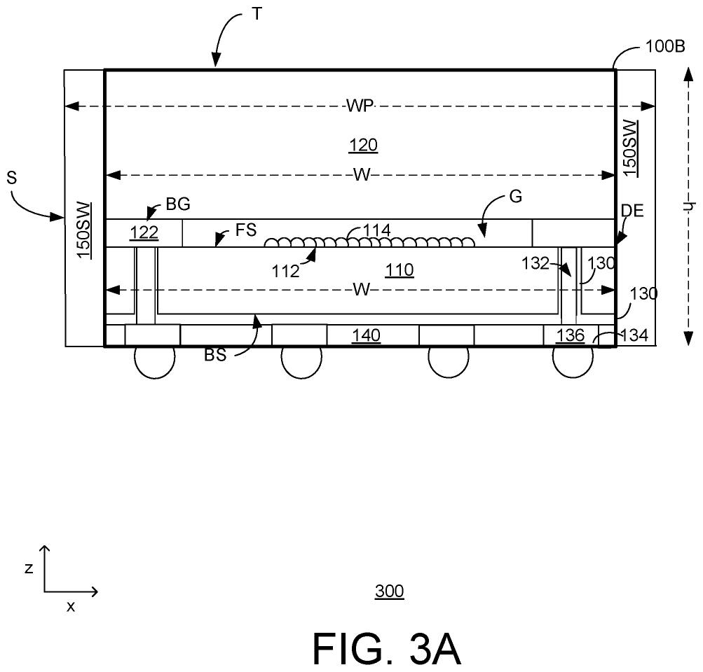

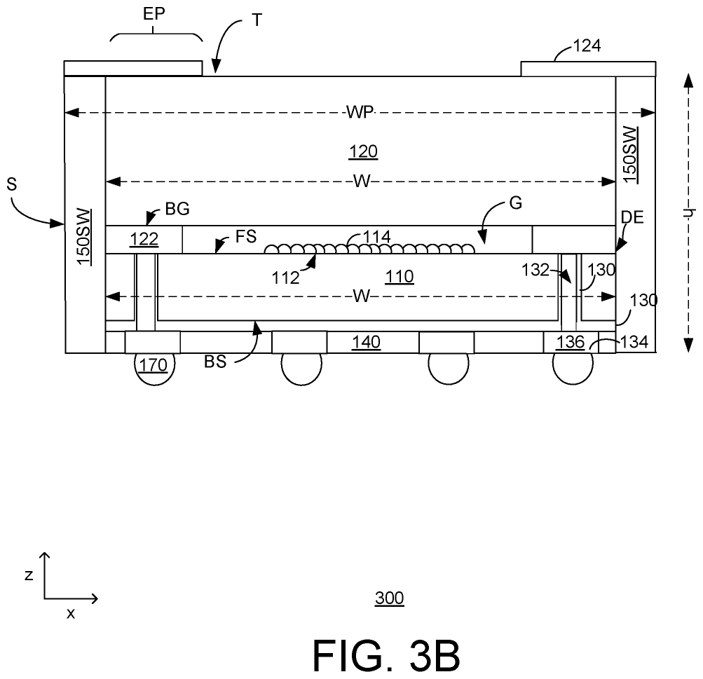

FIGS. 3A and 3B show cross-sectional views of an example image sensor package 300 that is hermetically sealed on sides of the image sensor die-glass cover assembly by four sidewall mold layers (e.g., sidewall mold layer 150SW).

Image sensor package 300 shown in FIG. 3A, like package 200 shown in FIG. 2A, includes an image sensor die-glass cover assembly (e.g., an image sensor die-glass cover assembly 100B). The image sensor die-glass cover assembly is hermetically sealed by four sidewall mold layers (e.g., sidewall mold layer 150SW). In image sensor package 300, the four sidewall mold layers (e.g., sidewall mold layer 150SW) may have a height h (in the z direction). A bottom of image sensor package 300 is formed by the first RDL layer (e.g., RDL 140) disposed on the passivation layer (e.g., passivation layer 130) disposed on bottom surface BS of image sensor die 110.

In image sensor package 300, the conductive traces or pads (e.g., contact pads 136) in the first RDL layer (e.g., RDL 140) are used as the external input/output pads of the package. Solder bumps 170 are disposed on the external input/output pads (e.g., contact pads 136) in the first RDL layer (e.g., RDL 140) so that the image sensor package 300 is surface mountable (e.g., on a printed circuit board) in circuit applications.

The combined structure of the image sensor die, the glass cover, the first redistribution layer, and the solder bumps shown in FIGS. 3A and 3B, may be referred to as the “image sensor die-glass cover assembly” (e.g., image sensor die-glass cover assembly 100B) of the package herein.

Image sensor package 300 shown in FIG. 3A, like image sensor package 100 shown in FIG. 1A, has the top surface (e.g., top surface T) of glass 120 that is a clear glass surface extending over a full width (e.g., width W) of the glass cover.

FIG. 3B shows package 300, like package 100 shown in FIG. 1B, with a light blocking material (e.g., light blocking material 124) disposed on edge portions (e.g., edge portion EP) of the top surface (e.g., top surface T) of glass 120.

In package 300 shown in FIGS. 3A and 3B, solder bumps 170 are disposed directly on the external input/output pads (e.g., contact pads 136) in the first RDL layer (e.g., RDL 140) in a first solder bumping process. In some implementations, a second solder bumping process can be used to place additional solder balls on RDL 140.

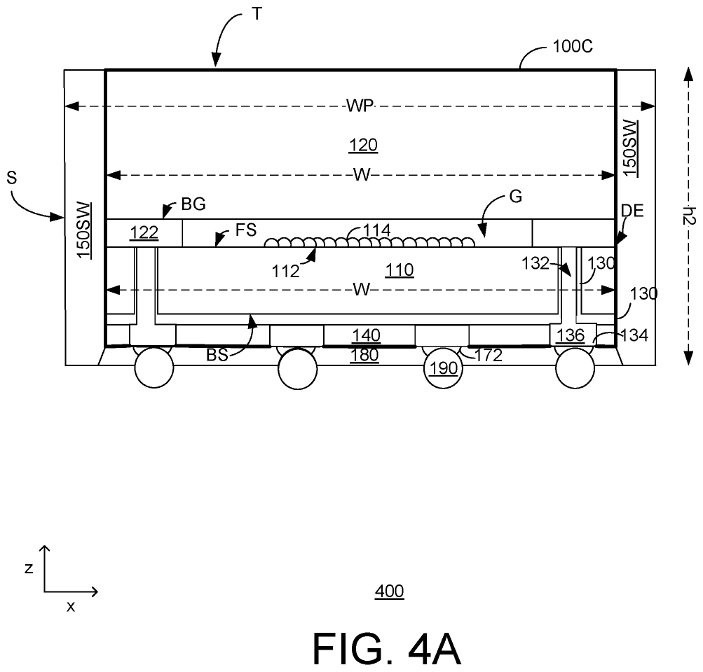

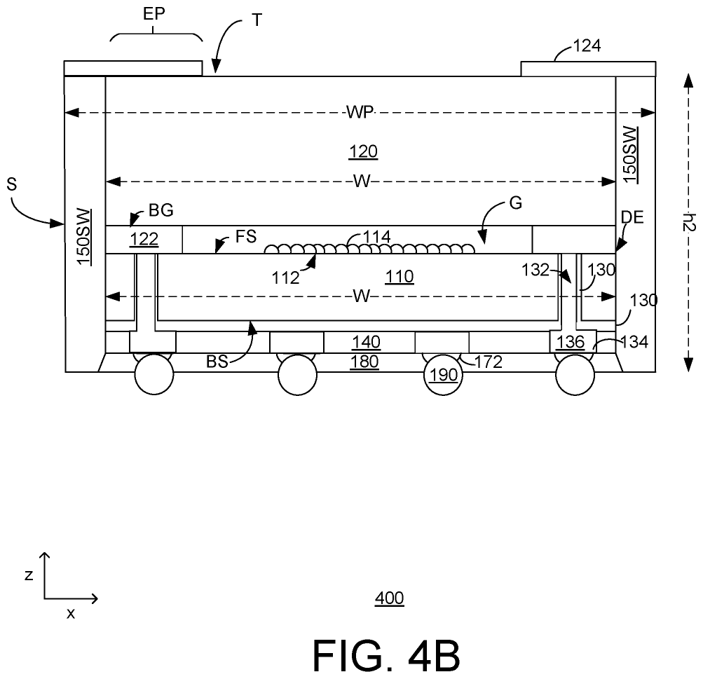

FIGS. 4A and 4B show cross-sectional views of an example image sensor package 400 in which a second solder bumping process performed through openings in a an underfill material (e.g., solder resist mask 180) to place additional solder balls (solder bumps 190) on the first RDL layer (e.g., RDL 140) connected to the external input/output pads (e.g., contact pads 136) in the first RDL layer (e.g., RDL 140).

As shown in FIGS. 4A and 4B, an underfill material (e.g., solder resist mask 180) may be disposed on the first RDL layer (e.g., RDL 140) with openings (not shown) aligned with the solder bumps (e.g., solder bumps 170, FIG. 3A) already present on the first RDL layer (e.g., RDL 140) from the first bumping process. The second solder bumping process places additional solder balls (solder bumps 190) aligned with the external input/output pads on the first RDL layer (e.g., RDL 140). The solder bumps (e.g., solder bumps 170, FIG. 3A) already present may reflow and interconnect to solder bumps 190 and the external input/output pads (e.g., contact pads 136) in the first RDL layer (e.g., RDL 140).

The combined structure of the image sensor die, the glass cover, the first redistribution layer, and the solder resist mask shown in FIGS. 4A and 4B, may be referred to as the “image sensor die-glass cover assembly” (e.g., image sensor die-glass cover assembly 100C) of the package herein.

Image sensor package 400 shown in FIGS. 4A and 4B includes an image sensor die-glass cover assembly (e.g., image sensor die-glass cover assembly 100C). Image sensor die-glass cover assembly 100C is hermetically sealed by four sidewall mold layers (e.g., sidewall mold layer 150SW) disposed on sidewalls of the assembly. The four sidewall mold layers may have a height h2 (in the z direction).

In image sensor package 400, the conductive traces or pads (e.g., contact pads 136) in the first RDL layer (e.g., RDL 140) are used as the external input/output pads of the package. Solder bumps 190 (with underfill 172) are disposed on the external input/output pads (e.g., contact pads 136) in the first RDL layer (e.g., RDL 140) so that the image sensor package 400 is surface mountable (e.g., on a printed circuit board) in circuit applications.

Image sensor package 400 shown in FIG. 4A, like image sensor package 100 shown in FIG. 1A, has the top surface (e.g., top surface T) of glass 120 that is a clear glass surface extending over a full width (e.g., width W) of the glass cover which is less that the full width (e.g., width WP) of the package.

FIG. 4B shows image sensor package 400, like image sensor package 100 shown in FIG. 1B, with a light blocking material (e.g., light blocking material 124) disposed on edge portions (e.g., edge portion EP) of the top surface (e.g., top surface T) of glass 120.

In the packages (e.g., image sensor package 100, image sensor package 200, image sensor package 300 and image sensor package 400) shown in FIGS 1A through FIG. 4B, the width of the glass cover (e.g., glass 120) is the same as the width W of the image sensor die in the package. In some example implementations, the glass cover may, for example, include slabs or layers of glass with different widths including at least one layer having a different (e.g., larger) width than the width W of the image sensor die. The glass cover may, for example, be shaped (in cross-sectional view) like a bottle stopper with a T-shape with a first layer (e.g., a base or a bottom layer) having a first width and a second layer (e.g., a top or a cap layer) having a second width larger than the first width.

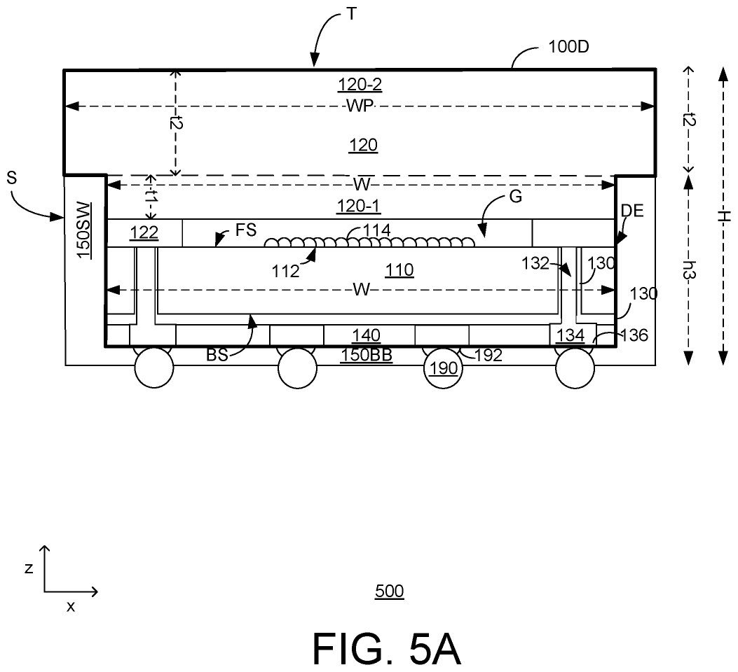

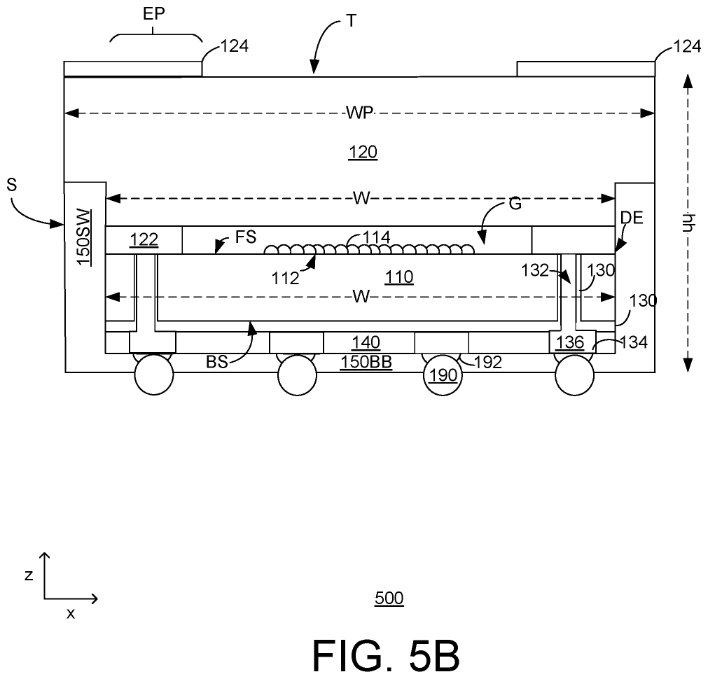

FIGS. 5A and 5B show cross-sectional views of an example image sensor package 500 in which the glass cover includes slabs or layers of different widths.

As shown in FIGS. 5A and 5B, glass 120 includes a first layer (e.g., layer 120-1) having a thickness t1 and a second layer (e.g., layer 120-2) having a thickness or height t2. Layer 120-1 may have a width that is the same as the width W of the image sensor die. Layer 120-1 may be attached to the image sensor die to image sensor die 110, for example, by the bead of the dam or adhesive material (e.g., dam 122) disposed on edges (e.g., edge DE) of the image sensor die. The second layer (e.g., layer 120-2) may be disposed above layer 120-1 (in the z direction). The second layer (e.g., layer 120-2) may have a width that is the same as the width WP of the package. A top surface T of layer 120-2 may be a clear glass surface extending over a full width (e.g., width WP) of the package.

The combined structure of the image sensor die, the glass cover having two layers with different widths, and the first redistribution layer, may be referred to as the “image sensor die-glass cover assembly” (e.g., image sensor die-glass cover assembly 100D) of the package herein.

In image sensor package 500, includes an image sensor die-glass cover assembly (e.g., image sensor die-glass cover assembly 100D). Image sensor die-glass cover assembly 100C is hermetically sealed by four sidewall mold layers (e.g., sidewall mold layer 150SW) that are disposed (as shown in FIG. 4A) on portions of the sidewalls of the image sensor die-glass cover assembly 100C that are below (in the z direction) the top layer of the glass cover (e.g., layer 120-2). Further, a bottom mold layer 150BB may be disposed on the first RDL layer (e.g., RDL 140). Bottom mold layer 150BB may (like solder resist mask 180, FIG. 4A) may include openings (not shown) aligned with the solder bumps (e.g., solder bumps 170, FIG. 3A) already present on the first RDL layer (e.g., RDL 140). In image sensor package 500, solder bumps 190 (with underfill 172) are disposed the conductive traces or pads (e.g., contact pads 136) in the first RDL layer (e.g., RDL 140) using bottom mold layer 150BB as a solder resist mask.

In image sensor package 500, the conductive traces or pads (e.g., contact pads 136) in the first RDL layer (e.g., RDL 140) are used as the external input/output pads of the package. Solder bumps 190 (with underfill 172) are disposed on the external input/output pads (e.g., contact pads 136) in the first RDL layer (e.g., RDL 140) so that the image sensor package 500 is surface mountable (e.g., on a printed circuit board) in circuit applications.

Image sensor package 500 shown in FIG. 5A has the top surface (e.g., top surface T) of glass 120 that is a clear glass surface extending over a full width (e.g., width WP) of the package.

FIG. 5B shows image sensor package 500, like image sensor package 100 shown in FIG. 1B, with a light blocking material (e.g., light blocking material 124) disposed on edge portions (e.g., edge portion EP) of the top surface (e.g., top surface T) of glass 120.

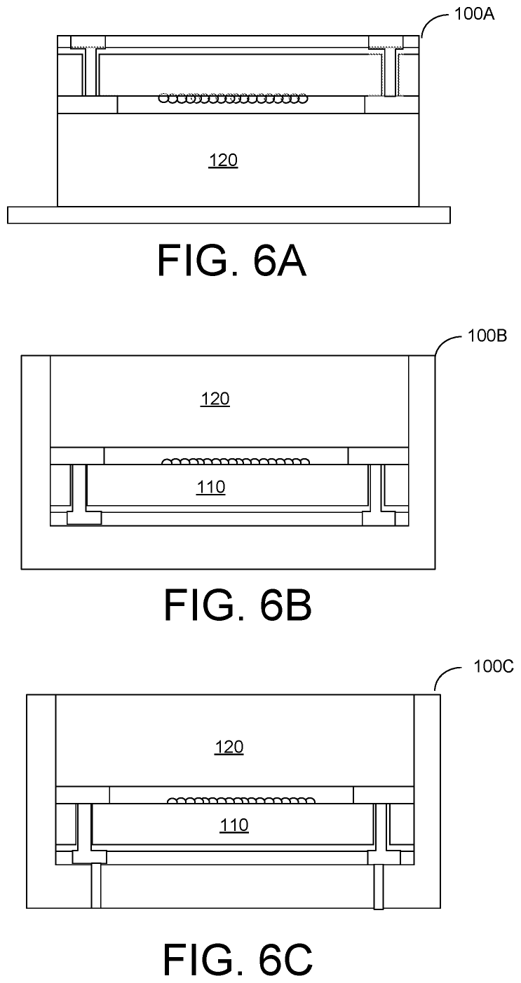

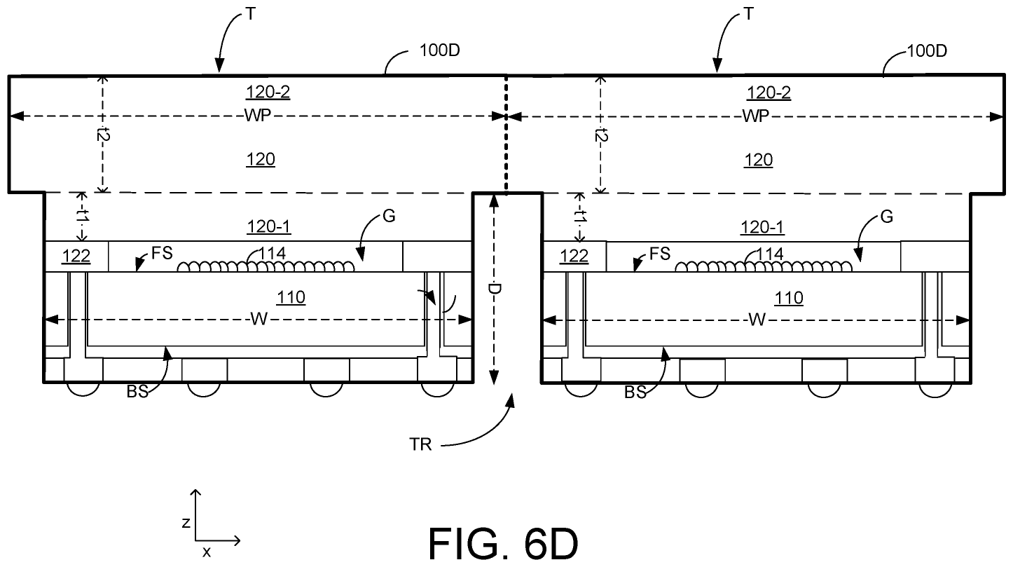

Individual image sensor die-glass cover assemblies (e.g., image sensor die-glass cover assembly 100A, 100B, 100C, 100D) used in the packages (e.g., image sensor package 100, 200, 300, 400 and 500) may be fabricated by forming individual image sensor die (e.g., image sensor die 110) in a semiconductor substrate and placing a sheet of glass (e.g., glass 120) over the semiconductor substrate. The sheet of glass can be attached to image sensor die 110, for example, by a bead of a dam or adhesive material (e.g., dam 122) disposed on edges (e.g., edge DE) of the image sensor die. The semiconductor substrate with the sheet of glass attached to it may be singulated to separate individual image sensor die-glass cover assemblies (e.g., image sensor die-glass cover assembly 100A, 100B, 100C). FIG. 6A, FIG. 6B, and FIG. 6C show, for example, separated individual image sensor die-glass cover assemblies (e.g., image sensor die-glass cover assembly 100A, 100B and 100C) that may be singulated from the semiconductor substrate.

In some implementations, the semiconductor substrate with the sheet of glass attached to it may be sawed from the back side (i.e., the side behind the image sensor die) through a thickness of the semiconductor substrate but sawed only through a part (e.g., thickness t1) of the total thickness (e.g., thickness t1+thickness t2) of the attached sheet of glass to form a trench between two adjoining image sensor die (with the two adjoining image sensor die remaining structurally joined by the un-sawn thickness (e.g., thickness t2) of the sheet of the glass). FIG. 6D shows, an example, an individual image sensor die-glass cover assembly 100D that is partially separated from an adjoining image sensor die-glass cover assembly 100D by a trench TR of limited depth (e.g., depth D) but remains structurally joined to the adjoining image sensor die-glass cover assembly 100D by an un-sawn thickness (e.g., thickness t2) of the sheet of the glass.

In example implementations of the packages described herein (e.g., package 100, 200, 300, 400, and 500, etc.) light blocking material (e.g., light blocking material 124, light blocking material 125) may be disposed on edge portions of the top surface (e.g., surface T) and/or the bottom surface (surface BG) of the glass cover (e.g., glass 120) attached over the image sensor die to prevent light incident at side angles from reaching the optically active sensor area (e.g., OASA 112) of the image sensor die

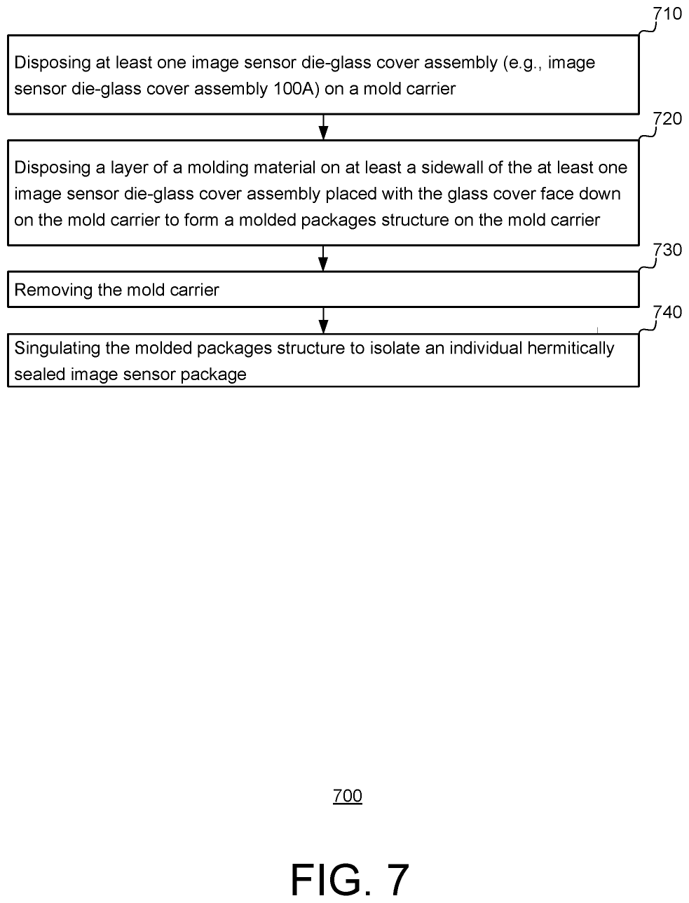

FIG. 7 shows an example method 700 for fabricating a hermetically sealed image sensor package with protective molding material layers disposed on the sidewalls of an enclosed image sensor die.

Method 700 includes disposing at least one image sensor die-glass cover assembly (e.g., image sensor die-glass cover assembly 100A) on a mold carrier (710). The mold carrier may be made of semiconductor material, a metal, a plastic, or any other material. The mold carrier can have a circular shape (e.g., like a circular (round) semiconductor wafer) or rectangular shape (e.g., like a rectangular strip).

In some implementations, disposing the at least one image sensor die-glass cover assembly may include placing the at least one image sensor die-glass cover assembly with the glass cover down on the mold carrier (in other words, with a top surface of the glass cover in contact with the mold carrier and a back side of the image sensor die facing up).

In some other implementations, disposing the at least one image sensor die-glass cover assembly may include placing the at least one image sensor die-glass cover assembly with the glass cover up away from the mold carrier (in other words, with a top surface of the glass cover away from the mold carrier and a back side of the image sensor die closer to the mold carrier).

In some implementations, the at least one image sensor die-glass cover assembly may be an individual image sensor die-glass cover assembly that is fully separated (i.e., singulated) from a next image sensor die-glass cover assembly.

In some other implementations, the at least one image sensor die-glass cover assembly may be partially isolated (singulated) from an adjoining image sensor die-glass cover assembly by a trench of a limited depth sawn between the at least one image sensor die-glass cover assembly and the adjoining image sensor die-glass cover assembly. The at least one image sensor die-glass cover assembly may be structurally connected to the adjoining image sensor die-glass cover assembly by an un-sawn thickness of the attached glass cover.

Method 700 further includes disposing a layer of a molding material on at least a sidewall of at least one image sensor die-glass cover assembly disposed with the glass cover down on the mold carrier to form a molded packages structure on the mold carrier (720), and removing the mold carrier (730), and singulating the molded packages structure to separate an individual hermitically sealed image sensor package (740).

In some implementations, method 700 may further include disposing a light blocking material (e.g., light blocking material 124) on edge portions (e.g., edge portion EP) of a top surface (e.g., top surface T) of the glass cover in an individual hermitically sealed image sensor package.

In some implementations, the at least one image sensor die-glass cover assembly can be an assembly that is partially separated from an adjoining image sensor die-glass cover assembly by a trench of limited depth (e.g., depth D) but remains structurally joined to the adjoining image sensor die-glass cover assembly 100D by an un-sawn thickness (e.g., thickness t2) of the glass cover. In such implementations, disposing a molding material on at least a sidewall of at least one image sensor die-glass cover assembly disposed with the glass cover down on the mold carrier to form a molded packages structure on the mold carrier 720 may include disposing the molding material in the trench.

In some implementations, method 700 disposing a molding material on at least a sidewall of at least one image sensor die-glass cover assembly disposed with the glass cover down on the mold carrier to form a molded packages structure on the mold carrier 720 can further include disposing a layer of the molding material on a bottom side (i.e., a side opposite the glass cover) of the at least one image sensor die-glass cover assembly (e.g., before removing the mold carrier 730). In such implementations where the molding material is disposed on the bottom side of the at least one image sensor die-glass cover assembly, method 700 further includes forming structures in or on the molded packages structure for making external electrical package connections to the enclosed at least one image sensor die. The structures for the electrical connections may, for example, include at least one of a through-mold via (TMV), a redistribution layer, and a solder bump.

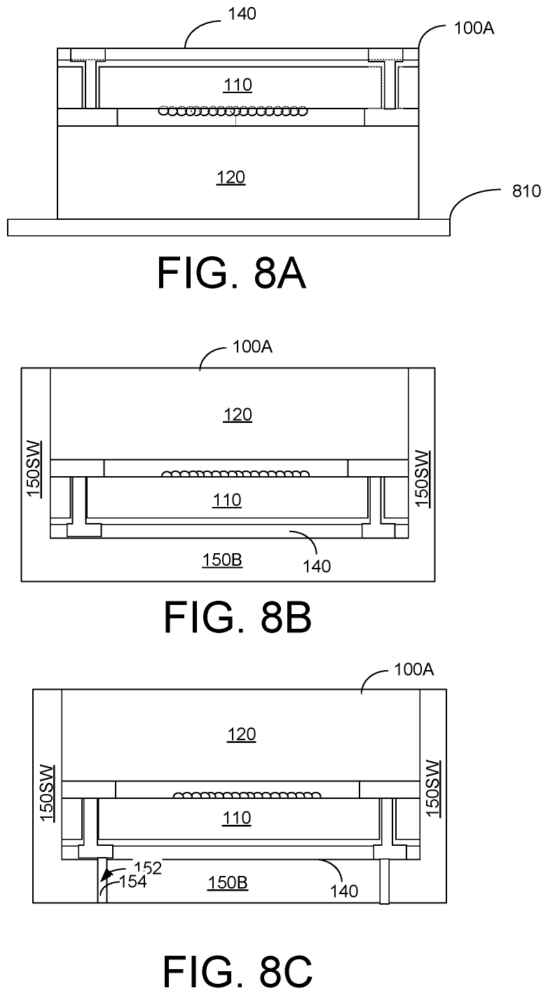

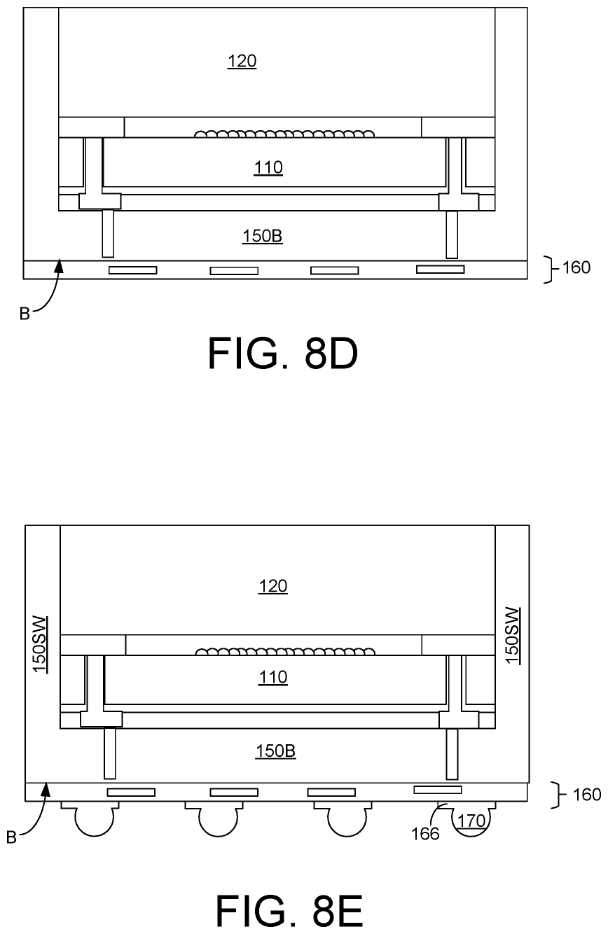

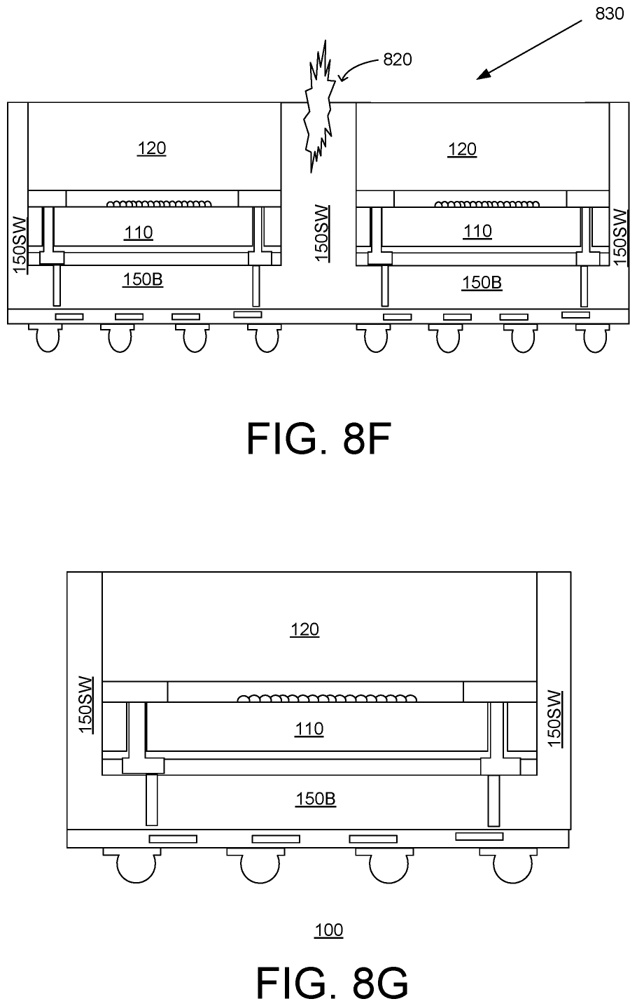

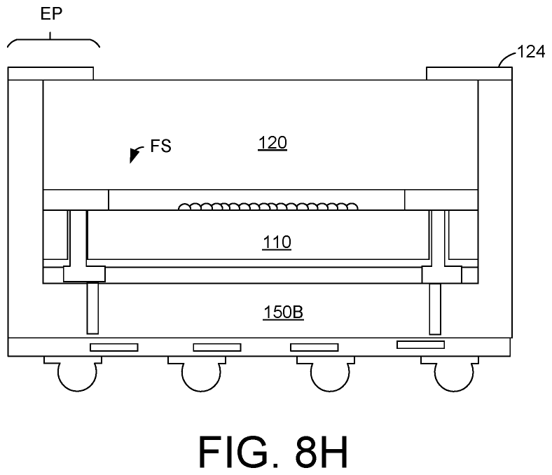

FIGS. 8A through 8G schematically illustrate an image sensor package (e.g., image sensor package 100, FIGS. 1A and IB) at different stages of construction, or after the different steps of method 700 for image sensor package with protective molding material layers disposed on the sidewalls of an enclosed image sensor die. FIGS. 8A through 8G show cross-sectional views of the image sensor package at the different stages of construction.

FIG. 8A shows an example image sensor die-glass cover assembly (e.g., image sensor die-glass cover assembly 100A) at an initial stage of construction of the package. Image sensor die-glass cover assembly 100A includes an image sensor die 110, a first RDL 140 disposed on a back side of the image sensor die, and cover (e.g., glass 120 disposed above the image sensor die. At least one image sensor die-glass cover assembly 100A is disposed with glass 120 face down on a mold carrier (e.g., substrate 810).

FIG. 8B shows the image sensor die-glass cover assembly at a second stage of construction of the package after molding material layers (e.g., sidewall mold layer 150SW, bottom mold layer 150B) are applied to sidewalls and the bottom of image sensor die-glass cover assembly 100A to form a molded packages structure (e.g., molded packages structure 830, FIG. 8F), and the mold carrier (e.g., substrate 810) is removed. FIG. 8B shows the image sensor die-glass cover assembly 100A in a vertically flipped orientation compared to the orientation shown in FIG. 8A.

FIG. 8C shows the image sensor die-glass cover assembly at a third stage of construction of the package after through-mold vias (e.g., TMV 152) are formed in the bottom mold layers (e.g., layer 150B) disposed the bottom of image sensor die-glass cover assembly 100A, and the mold carrier is removed.

FIG. 8D shows the image sensor die-glass cover assembly at a fourth stage of construction of the package after a second redistribution layer (RDL 160) is disposed on the bottom B of the bottom mold layer (e.g., mold layer 150B) for electrical connections to the image sensor die in the package.

FIG. 8E shows the image sensor die-glass cover assembly at a fifth stage of construction of the package after external input/output pads (e.g., pads 166) and solder bumps 170 are disposed on RDL 160 for electrical connections to the image sensor die in the package. The formation of TMV 152, RDL 160, and external input/output pads (e.g., pads 166) and solder bumps 170 may involve wafer-level processing (e.g., lithography, patterning, masking, etching and deposition processing) of the molded packages structure formed at earlier stages (e.g., the second stage) of the construction).

FIG. 8F pictorially illustrates singulation (e.g., using a saw 820) of a molded packages structure 830 at a sixth stage of construction of the package. The singulation separates an individual hermitically sealed image sensor package (e.g., image sensor package 100) from the molded packages structure 830 formed at the fifth stage of construction.

FIG. 8G shows a cross-sectional view of an individual hermitically sealed image sensor package (e.g., image sensor package 100) separated from the molded package structure by singulation.

FIG. 8H shows a cross-sectional view of the image sensor package (e.g., image sensor package 100) in which a light blocking material (e.g., light blocking material 124) is further disposed on edge portions (e.g., edge portion EP) of a top surface (e.g., top surface T) of the glass cover. The light blocking material (e.g., light blocking material 124) may be deposited on the edge portions using lithographic patterning and deposition techniques.

In some implementations, instead of disposing a second redistribution layer (e.g., RDL 160) on the bottom B of the bottom mold layer (e.g., mold layer 150B) (e.g., at stage four of the construction), external input/output pads (e.g., pads 166) of the package are disposed directly on the bottom mold layer (e.g., mold layer 150B). Solder bumps 170 are disposed on the external input/output pads (e.g., pads 166) on mold layer 150B of the package so that the image sensor package is surface mountable (e.g., on a printed circuit board) in circuit applications.

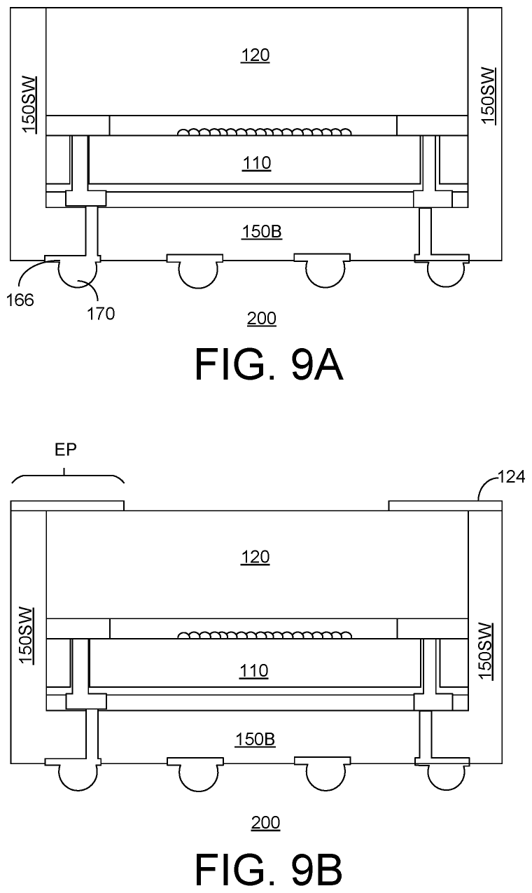

FIG. 9A schematically illustrates an image sensor package (e.g., image sensor package 200, FIG. 2A) having external input/output pads (e.g., pads 166) disposed directly on the bottom mold layer (e.g., mold layer 150B) and solder bumps 170 disposed on the external input/output pads (e.g., pads 166) in wafer level processes before the singulation at sixth stage of construction.

FIG. 9B shows a cross-sectional view of the image sensor package (e.g., package 200) in which a light blocking light blocking material (e.g., light blocking material 124) is further disposed on edge portions (e.g., edge portion EP) of a top surface (e.g., top surface T) of the glass cover. The light blocking material (e.g., light blocking material 124) may be deposited on the edge portions using lithographic patterning and deposition techniques.

Some packages (e.g., package 300, FIGS. 3A and 3B) are hermetically sealed only by the four sidewall mold layers (e.g., sidewall mold layer 150SW). There may be no mold layer (e.g., the mold layer 150B, FIGS. 2A and 2B) disposed on the bottom side of the package (i.e., on the first redistribution layer (RDL 140) on the back side (e.g., bottom surface BS) of image sensor die 110, FIGS. 2A and 2B).

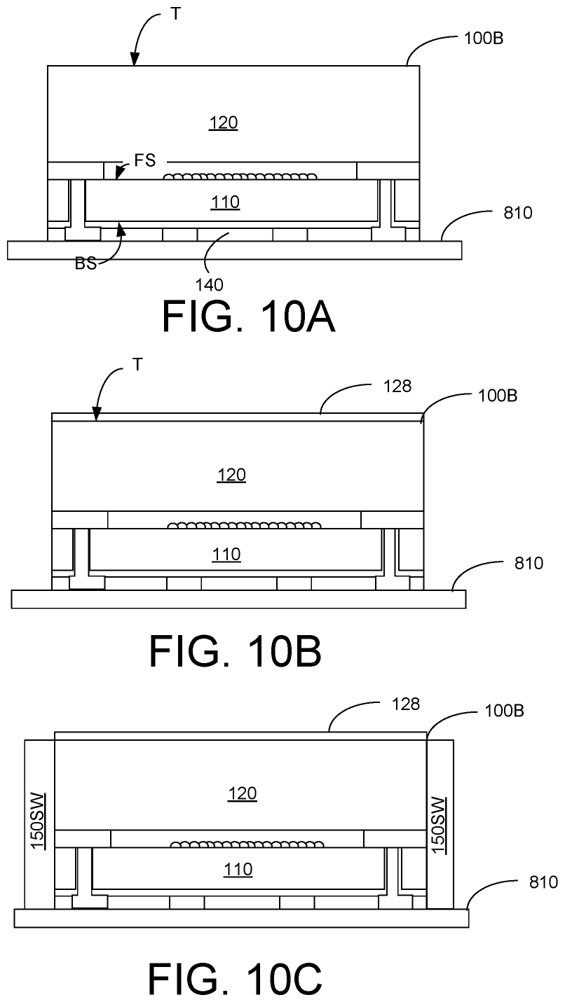

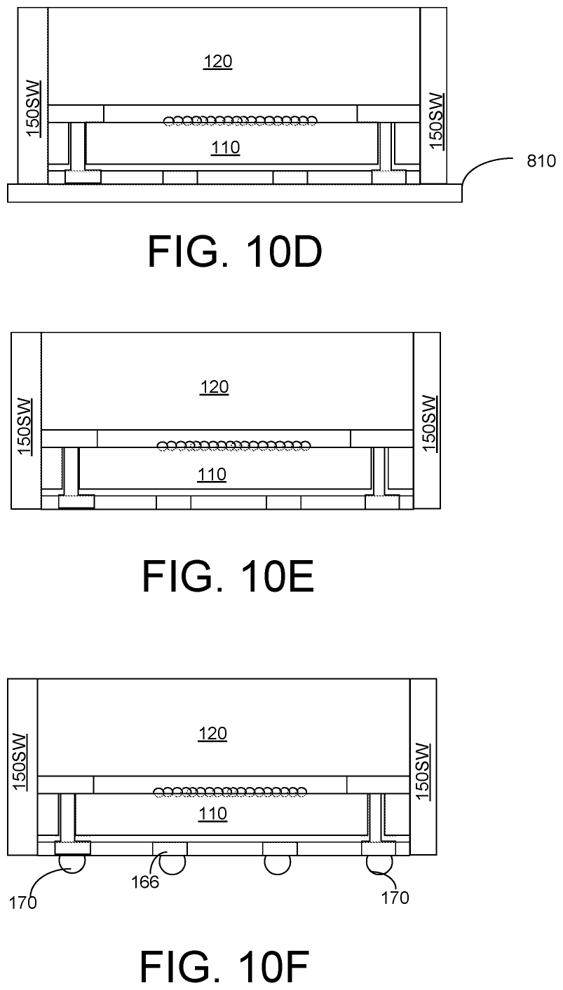

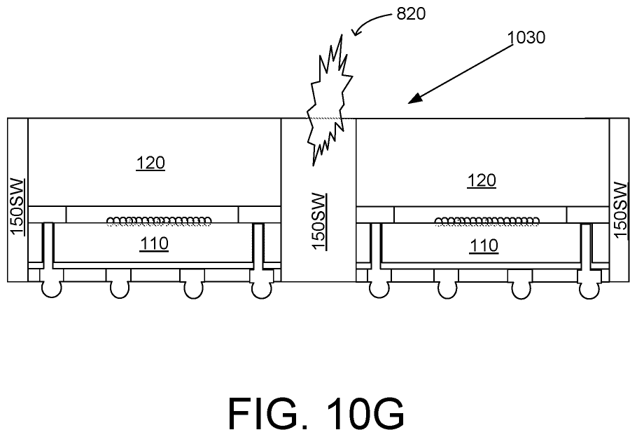

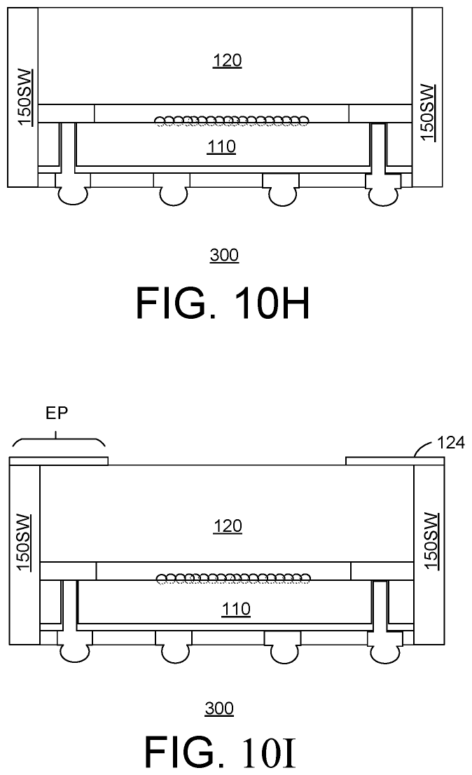

FIGS. 10A through 10I schematically illustrate an image sensor package (e.g., image sensor package 300, FIGS. 2A and 2B) at different stages of construction, or after the different steps of method 700 for image sensor package with protective molding material layers disposed on the sidewalls of an enclosed image sensor die.

FIGS. 10A through 10I show cross-sectional views of the image sensor package at the different stages of construction.

FIG. 10A shows an example image sensor die-glass cover assembly (e.g., image sensor die-glass cover assembly 100B) at an initial stage of construction of the package. Image sensor die-glass cover assembly 100B includes an image sensor die 110, a first RDL 140 disposed on a back side of the image sensor die, and cover (e.g., glass 120 disposed above a frontside of the image sensor die. At least one image sensor die-glass cover assembly 100A is disposed with first RDL 140 face down on a mold carrier (e.g., substrate 810) with glass 120 face up away from substrate 810.

FIG. 10B shows the image sensor die-glass cover assembly at a second stage of construction of the image sensor package with a protective layer (e.g., release layer 128) (e.g., an adhesive tape) disposed on a top surface T of the glass cover (glass 120) to protect the top surface T during molding processes.

FIG. 10C shows the image sensor die-glass cover assembly at a third stage of construction of the package with molding material layers (e.g., sidewall mold layer 150SW) disposed on sidewalls of image sensor die-glass cover assembly 100B to form a molded packages structure (e.g., molded packages structure 830, FIG. 8F) on the mold carrier (e.g., substrate 810).

FIG. 10D shows the image sensor die-glass cover assembly at a fourth stage of construction of the package after the protective layer (e.g., release layer 128) disposed on the top surface T of the glass cover (glass 120) to protect the top surface T during molding processes is removed.

FIG. 10E shows the image sensor die-glass cover assembly at a fifth stage of construction of the package after the mold carrier (e.g., substrate 810) is removed.

FIG. 10F shows the image sensor die-glass cover assembly at a sixth stage of construction of the package after solder bumps 170 are disposed on external input/output pads (e.g., pads 166) in RDL 140 for electrical connections to the image sensor die in the package. Disposing solder bumps on the external input/output pads (e.g., pads 166) in RDL 140 may involve wafer-level solder bumping techniques.

FIG. 10G pictorially illustrates singulation (e.g., using a saw 820) of the molded packages structure 1030 at a sixth stage of construction of the package. The singulation separates an individual hermitically sealed image sensor package (e.g., package 300) from the molded packages structure 1030 formed at the fifth stage of construction.

FIG. 10H shows a cross-sectional view of an individual hermitically sealed image sensor package (e.g., package 300) separated from the molded package structure by singulation.

FIG. 10I shows a cross-sectional view of the image sensor package (e.g., package 300) in which a light blocking material (e.g., light blocking material 124) is further disposed on edge portions (e.g., edge portion EP) of a top surface (e.g., top surface T) of the glass cover. The light blocking material (e.g., material 124) may be deposited on the edge portions using lithographic patterning and deposition techniques.

In some packages (e.g., package 400, FIGS. 4A and 4B), the enclosed image sensor die may already have a RDL layer and solder bumps (resulting from a first bumping process) disposed on a back side of the die. The solder bumps can be a metal pad (e.g., Ti, Cu or Al, Ni, Au or a combination thereof), a Cu bump, or any kind of solder material.

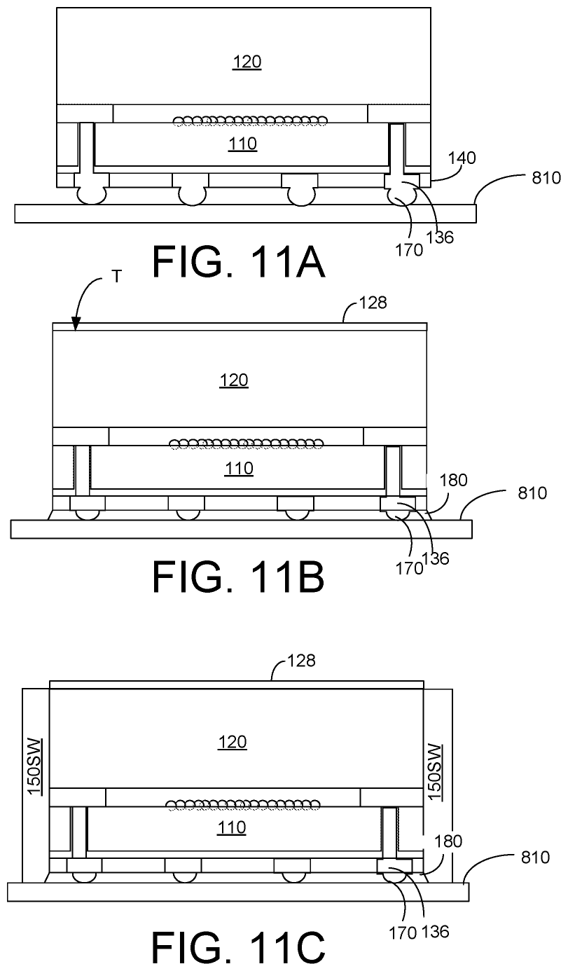

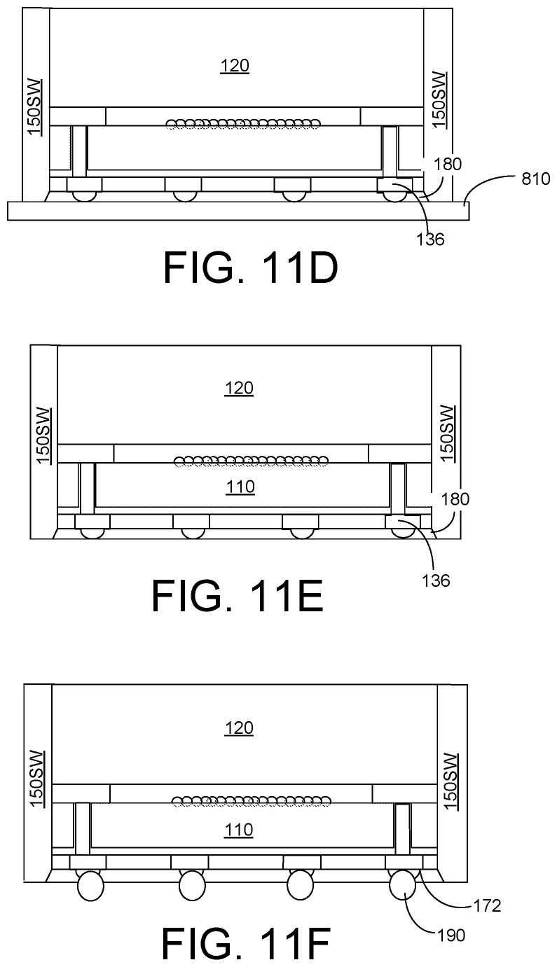

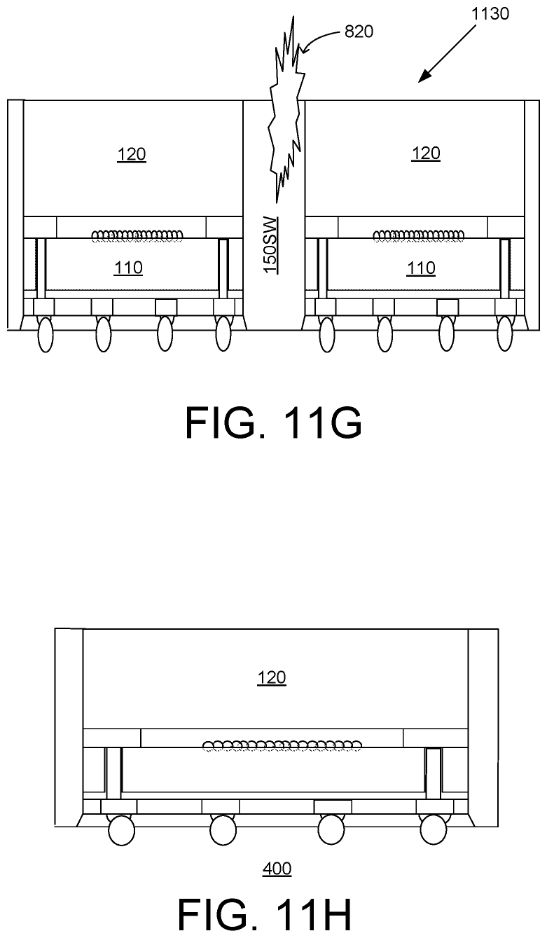

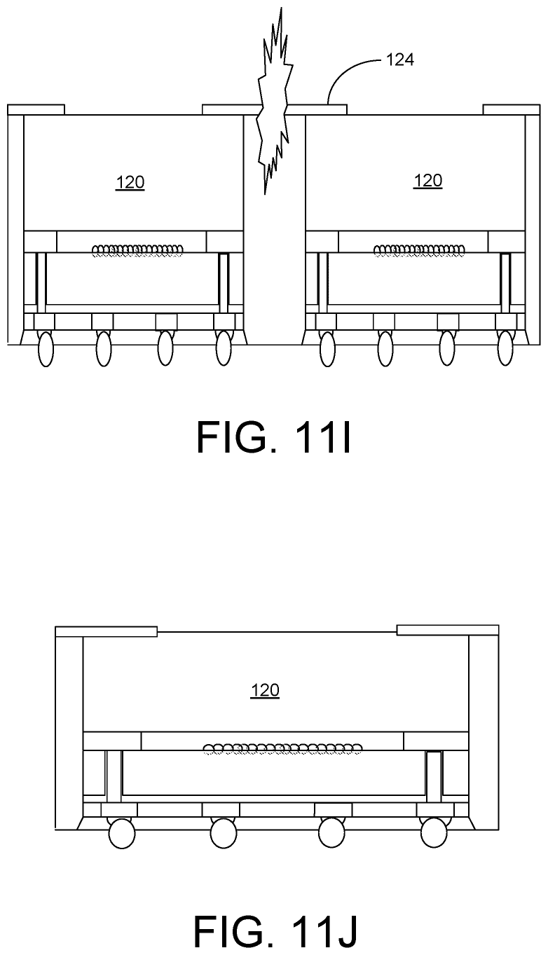

FIGS. 11A through 11I schematically illustrate an image sensor package (e.g., image sensor package 400, FIGS. 2A and 2B) at different stages of construction, or after the different steps of method 700 for image sensor package with protective molding material layers disposed on the sidewalls of an enclosed image sensor die.

FIGS. 11A through 11G show cross-sectional views of the image sensor package at the different stages of construction.

FIG. 11A shows an example image sensor die-glass cover assembly (e.g., image sensor die-glass cover assembly 100C, FIG. 4A) at an initial stage of construction of the package. Image sensor die-glass cover assembly 100C includes an image sensor die 110, a first RDL 140 disposed on a back side of the image sensor die, and a glass cover (e.g., glass 120) disposed above a frontside of the image sensor die, and solder bumps 170 (resulting from a first bumping process) disposed on a back side of the die. At least one image sensor die-glass cover assembly 100C is disposed on a mold carrier (e.g., substrate 810) with first RDL 140 face down on the mold carrier (e.g., substrate 810) with glass 120 face up away from substrate 810 and with solder bumps 170 resting on the mold carrier (e.g., substrate 810).

FIG. 11B shows the image sensor die-glass cover assembly at a second stage of construction of the image sensor package with a protective layer (e.g., release layer 128) (e.g., an adhesive tape) disposed on a top surface T of the glass cover (glass 120) to protect the top surface T during molding processes, and an underfill layer (e.g., solder resist mask 180) disposed between first RDL 140 and substrate 810 before the molding processes at the next stage of construction. The underfill layer (e.g., solder resist mask 180) may include openings (not shown) aligned with the solder bumps (e.g., solder bumps 170) already present on RDL 140 from the first bumping process.

FIG. 11C shows the image sensor die-glass cover assembly at a third stage of construction of the package with molding material layers (e.g., sidewall mold layer 150SW) disposed on sidewalls of image sensor die-glass cover assembly 100C to form a molded packages structure (e.g., molded packages structure 1130, FIG. 11G) on the mold carrier (e.g., substrate 810).

FIG. 11D shows the image sensor die-glass cover assembly at a fourth stage of construction of the package after the protective layer (e.g., release layer 128) disposed on the top surface T of the glass cover (glass 120) to protect the top surface T during molding processes is removed.

FIG. 11E shows the image sensor die-glass cover assembly at a fifth stage of construction of the package after the mold carrier (e.g., substrate 810) is removed.

FIG. 11F shows the image sensor die-glass cover assembly at a sixth stage of construction of the package after solder bumps 190 are disposed in a second bumping process on the external input/output pads (e.g., pads 166) in RDL 140 for electrical connections to the image sensor die in the package. The solder bumps (e.g., solder bumps 170, FIG. 3A) already present may form underfill material (e.g., underfill 172) between solder bumps 190 and the external input/output pads (e.g., contact pads 136) in the first RDL layer (e.g., RDL 140).

FIG. 11G pictorially illustrates singulation (e.g., using a saw 820) of the molded packages structure 1030 at a seventh stage of construction of the package. The singulation separates an individual hermitically sealed image sensor package (e.g., package 400) from the molded packages structure 1130 formed at the fifth stage of construction.

FIG. 11H shows a cross-sectional view of an individual hermitically sealed image sensor package (e.g., package 400) separated from the molded package structure by singulation.

FIG. 11I pictorially illustrates singulation (e.g., using a saw 820) of the molded packages structure 1030 in which a light blocking material (e.g., material 124) is disposed on edge portions (e.g., edge portion EP) of a top surface (e.g., top surface T) of the glass cover. The singulation separates an individual hermitically sealed image sensor package (e.g., package 400) from the molded packages structure 1130 formed at the fifth stage of construction.

FIG. 11J shows a cross-sectional view of the image sensor package (e.g., package 400) in which a light blocking material (e.g., light blocking material 124) is further disposed on edge portions (e.g., edge portion EP) of a top surface (e.g., top surface T) of the glass cover.

In some packages (e.g., package 500, FIGS. 5A and 5B), the glass cover includes slabs or layers of different widths. The glass cover (e.g., glass 120) includes a first layer (e.g., layer 120-1) having a thickness t1 and a second layer (e.g., layer 120-2) having a thickness or height t2. Layer 120-1 may have a width that is the same as the width W of the image sensor die. Layer 120-1 may be attached to the image sensor die to image sensor die 110, for example, by the bead of the dam or adhesive material (e.g., dam 122) disposed on edges (e.g., edge DE) of the image sensor die. Second layer 120-2 may be disposed above layer 120-1 (in the z direction). Layer 120-2 may have a width that is the same as the width WP of the package. A top surface T of layer 120-2 may be a clear glass surface extending over a full width (e.g., width WP) of the package.

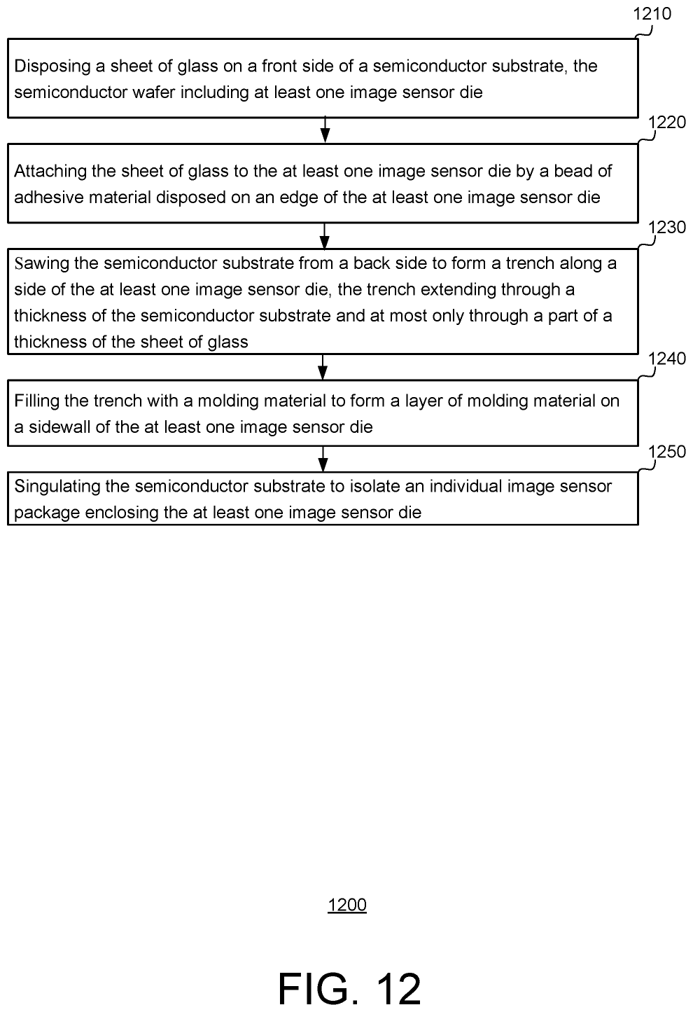

FIG. 12 illustrates an example method 1200 of fabricating chip scale image sensor packages using wafer level processing techniques.

Method 1200 includes disposing a sheet of glass on a front side of a semiconductor substrate (1210). The semiconductor substrate (e.g., a silicon wafer) includes at least one image sensor die. Method 1200 further includes attaching the sheet of glass to the at least one image sensor die by a bead of adhesive material disposed on an edge of the at least one image sensor die (1220), and sawing the semiconductor substrate from a back side to form a trench along a side of the at least one image sensor die, the trench extending through a thickness of the semiconductor substrate and at most only through a part of a thickness of the sheet of glass (1230). Method 1200 further includes filling the trench with a molding material to form a layer of molding material on a sidewall of the at least one image sensor die (1240), and singulating the semiconductor substrate to isolate an individual image sensor package enclosing the at least one image sensor die (1250).

Method 1200 may include before singulating the semiconductor substrate, disposing a layer of the molding material on a bottom side of the at least one image sensor die in the semiconductor substrate; and forming structures in or on the layer of the molding material disposed on the bottom side of the at least one image sensor die for making external electrical package connections to the at least one image sensor die. These structures for making external electrical package connections can include at least one of a through-mold via (TMV), a redistribution layer, and a solder bump.

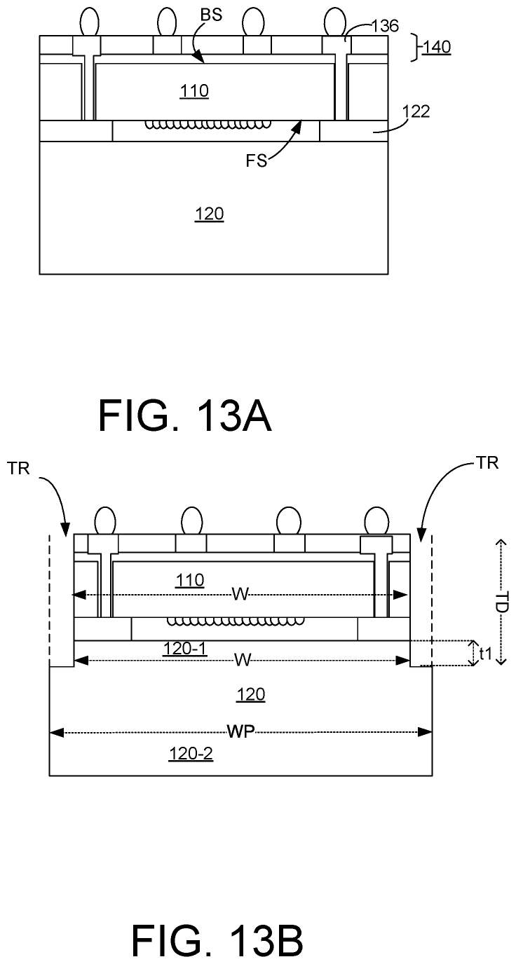

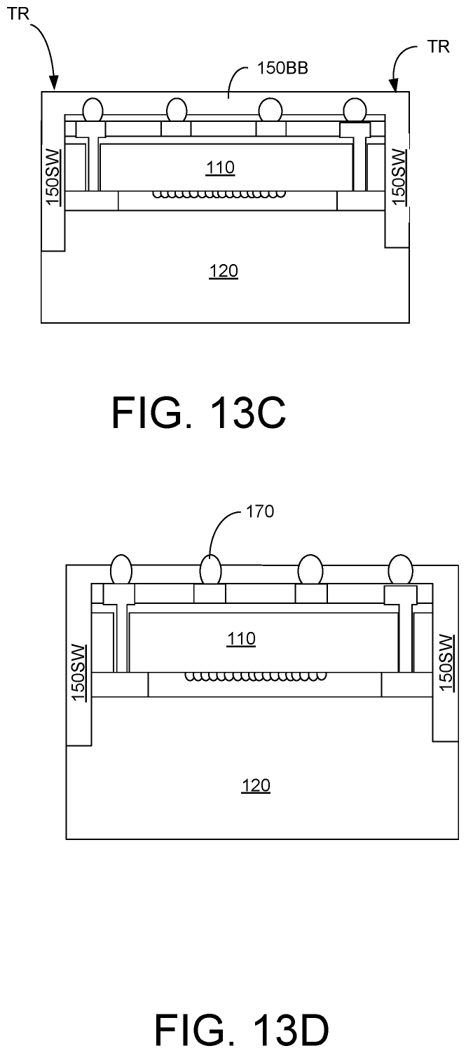

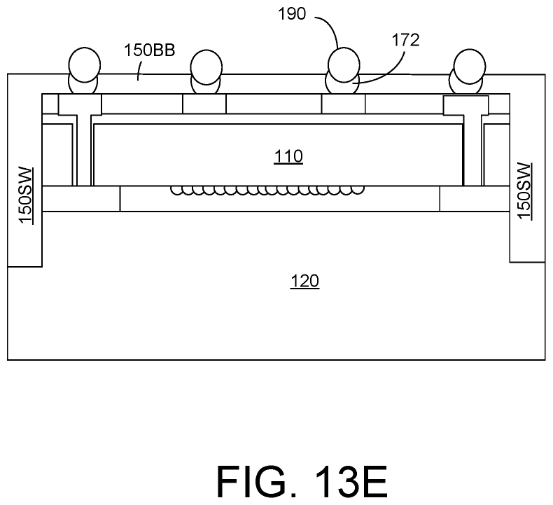

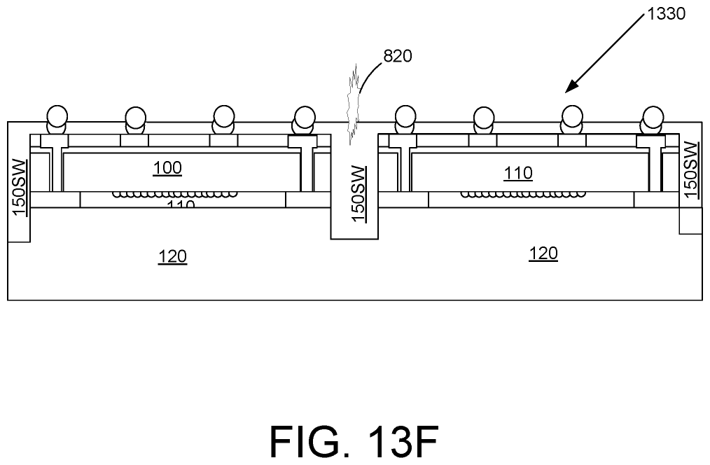

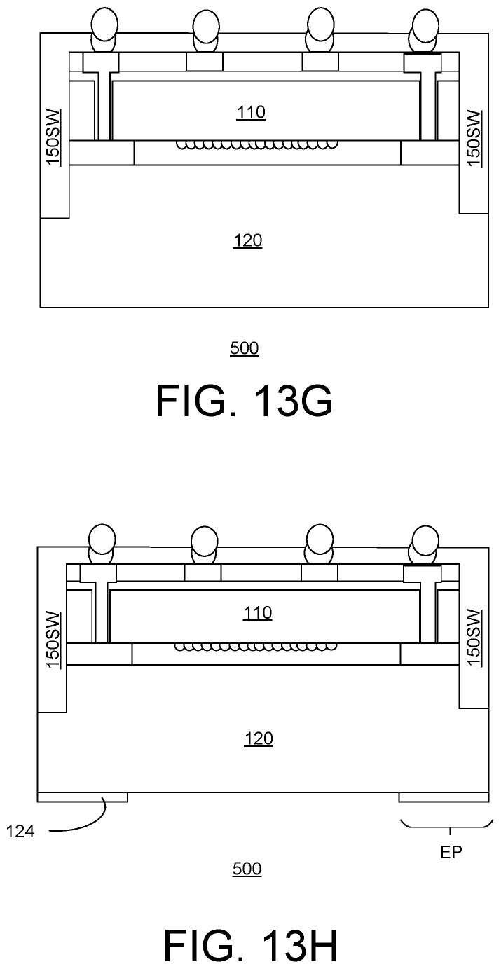

FIGS. 13A through 13H schematically illustrate an image sensor package (e.g., image sensor package 500, FIGS. 5A and 5B) at different stages of construction, or after the different steps of method 700 for image sensor package with protective molding material layers disposed on the sidewalls of an enclosed image sensor die.

FIGS. 13A through 13H show cross-sectional views of the image sensor package at the different stages of construction.

FIG. 13A shows an example image sensor die 110 assembled with glass 120 at an initial stage of construction of the package. Image sensor die 110 may be fabricated, for example, in a semiconductor substrate (e.g., a silicon wafer) (not shown). A first RDL 140 and solder bumps 170 (resulting from a first bumping process) are disposed on a back side BS of the image sensor die. A glass cover (e.g., glass 120) is disposed above a frontside FS of the image sensor die. Glass 120 may be a sheet of glass attached to the semiconductor substrate by dam material (e.g., dam 122) disposed on edges (e.g., edge DE) of the image sensor die.

FIG. 13B shows the image sensor die-glass cover assembly at a second stage of construction of the image sensor package. Trenches (e.g., trench TR) are etched from the frontside of the semiconductor substrate to isolate the image sensor die 110. A trench TR may have a depth TD such that the trench extends into the glass cover for a limited distance (e.g., a thickness t1 of a first layer 102-1 of the glass cover). Pairs of trenches TR may be separated by a distance equal to a width (e.g., width WP) of the package.

FIG. 13C shows the image sensor die-glass cover assembly at a third stage of construction of the image sensor package. At this stage of construction, a molding compound is applied to the semiconductor substrate filling the trenches (e.g., trench TR) with molding material that forms the protective sidewalls (e.g., sidewall mold layer 150SW) of the image sensor die-glass cover assembly. The molding compound may also be disposed on the first RDL layer (e.g., RDL 140) forming a bottom mold layer 150BB on RDL 140. The bottom mold layer may cover the solder bumps (e.g., solder bumps 170) disposed on RDL 140. The molding process applied to the semiconductor substrate may form a molded packages structure (e.g., molded packages structure 1330, FIG. 13F).

FIG. 13D shows the image sensor die-glass cover assembly at a fourth stage of construction of the image sensor package. At this stage of construction, the bottom mold layer 150BB disposed on RDL 140 is ground back partially to expose the solder bumps (e.g., solder bumps 170) covered at the third stage of construction by bottom mold layer 150BB.

FIG. 13E shows the image sensor die-glass cover assembly at a fourth stage of construction of the image sensor package. At this stage of construction, solder bumps 190 are disposed in a second bumping process on the external input/output pads (e.g., pads 166) in RDL 140 for electrical connections to the image sensor die in the package. The solder bumps (e.g., solder bumps 170) already present (after back grinding of bottom mold layer 150BB) may form underfill material (e.g., underfill 172) between solder bumps 190 and the external input/output pads (e.g., contact pads 136) in the first RDL layer (e.g., RDL 140).

FIG. 13F pictorially illustrates singulation (e.g., using a saw 820) of the semiconductor substrate (i.e., molded packages structure 1130) at a fifth stage of construction of the package. The singulation separates an individual hermitically sealed image sensor package (e.g., package 500) from the molded packages structure 1130 formed at the fourth stage of construction.

FIG. 13G shows a cross-sectional view of an individual hermitically sealed image sensor package (e.g., package 500) separated from the molded packages structure by singulation.

FIG. 13F shows a cross-sectional view of the image sensor package (e.g., package 500) in which a light blocking material (e.g., light blocking material 124) is further disposed on edge portions (e.g., edge portion EP) of a top surface (e.g., top surface T) of the glass cover. The light blocking coating (e.g., light blocking material 124) may be deposited on the edge portions using lithographic patterning and deposition techniques in substrate level processing before singulation.

In example implementations of the packages described herein (e.g., packages, 100, 200, 300, 400, and 500, etc.) light blocking material (e.g., light blocking material 124, light blocking material 125) may be disposed on edge portions of the top surface (e.g., surface T) and/or the bottom surface (surface BG) of the glass cover (e.g., glass 120) attached over the image sensor die.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

What is claimed is:

1. A package comprising:
an assembly of an image sensor die and a glass cover attached to the image sensor die, the glass cover being disposed above an optically active area on a front side of the image sensor die; and
a layer of molding material disposed on a sidewall of the assembly of the image sensor die and the glass cover, the layer of molding material hermetically sealing the assembly of the image sensor die and the glass cover.

2. The package of claim 1, wherein the glass cover has a width that is a same as a width of the image sensor die.

3. The package of claim 1, wherein a width of the package including the layer of molding material disposed on the sidewall of the assembly is no greater than 120% of a width of the image sensor die.

4. The package of claim 1, wherein the glass cover includes:
a first layer of glass attached to the image sensor die, the first layer of glass having a width that is a same as a width of the image sensor die; and
a second layer of glass disposed above the first layer of glass, the second layer of glass having a width greater than the width of the image sensor die.

5. The package of claim 4, wherein the layer of molding material is disposed on a portion of the sidewall of the assembly that is below the second layer of glass.

6. The package of claim 1, wherein an edge portion of a top surface of the glass cover is coated with a light blocking material.

7. The package of claim 1, further comprising:
a signal redistribution layer disposed on a back side of the image sensor die; and
a through-semiconductor via (TSV) providing electrical connections between the front side of the image sensor die and the back side of the image sensor die.

8. The package of claim 7, further comprising:
external input/output pads and solder bumps for electrical connections to the image sensor die in the package, the external input/output pads being disposed on the signal redistribution layer that is disposed on a back side of the image sensor die.

9. The package of claim 7, further comprising, a layer of molding material is disposed on the signal redistribution layer that is disposed on the back side of the image sensor die, the layer of molding material hermetically sealing a back side of the assembly of the image sensor die and the glass cover.

10. The package of claim 9, wherein the signal redistribution layer disposed on the back side of the image sensor die is a first signal redistribution layer and the package further includes a second signal redistribution layer disposed on a bottom of the layer of molding material that is disposed on the first signal redistribution layer.

11. The package of claim 10, further comprising:
a through-mold via (TMV) that electrically connects the first signal redistribution layer on the back side of image sensor die and the second signal redistribution layer disposed on the bottom of the layer of molding material.

12. The package of claim 10, further comprising:
external input/output pads and solder bumps for electrical connections to the image sensor die in the package, the external input/output pads and solder bumps being disposed on the second signal redistribution layer that is disposed on a bottom of the layer of molding material.

13. A package comprising:
an image sensor die;
a glass cover disposed above the image sensor die, at least a top layer of the glass cover having a width greater than a width of the image sensor die, the glass cover being attached to the image sensor die by a bead of adhesive material placed on an edge of the image sensor die; and
a layer of molding material disposed on a sidewall of the image sensor die, the layer of molding material hermetically sealing the image sensor die and the glass cover.

14. The package of claim 13, wherein the layer of molding material disposed on the sidewall of the image sensor die extends along a side of a bottom layer of the glass cover, the bottom layer having a smaller width than the width of the top layer of the glass cover.

15. The package of claim 13, further comprising:
a signal redistribution layer disposed on a back side of the image sensor die; and
a through-semiconductor via (TSV) providing electrical connections between a front side of the image sensor die and the back side of the image sensor die.

16. The package of claim 15, further comprising:
a layer of molding material disposed on the signal redistribution layer that is disposed on the back side of the image sensor die, the layer of molding material hermetically sealing the back side of the image sensor die.

17. The package of claim 15, further comprising:
external input/output pads and solder bumps for electrical connections to the image sensor die in the package, the external input/output pads being disposed on the layer of molding material that is disposed on the signal redistribution layer.

18. A method comprising:
disposing at least one assembly of an image sensor die and a glass cover on a carrier;
disposing a layer of a molding material on at least a sidewall of the at least one assembly placed with a top surface of the glass cover down on the carrier to form a molded packages structure on the carrier;
removing the carrier; and
singulating the molded packages structure to isolate an individual hermitically sealed image sensor package.

19. The method of claim 18 further comprising:
disposing a layer of the molding material on a bottom side of the at least one assembly of the image sensor die and the glass cover; and
forming structures in or on the molded packages structure for making external electrical package connections to the at least one assembly of the image sensor die and the glass cover, the structures including at least one of a through-mold via (TMV), a redistribution layer, and a solder bump.

20. A method, comprising:
disposing a sheet of glass on a front side of a semiconductor substrate, the semiconductor substrate including at least one image sensor die;
attaching the sheet of glass to the at least one image sensor die by a bead of adhesive material disposed on an edge of the at least one image sensor die;
sawing the semiconductor substrate from a back side to form a trench along a side of the at least one image sensor die, the trench extending through a thickness of the semiconductor substrate and at most only through a part of a thickness of the sheet of glass;
filling the trench with a molding material to form a layer of molding material on a sidewall of the at least one image sensor die; and
singulating the semiconductor substrate to isolate an individual image sensor package enclosing the at least one image sensor die.

21. The method of claim 20 further comprising:
before singulating the semiconductor substrate, disposing a layer of the molding material on a bottom side of the at least one image sensor die in the semiconductor substrate; and
forming structures in or on the layer of the molding material disposed on the bottom side of the at least one image sensor die for making external electrical package connections to the at least one image sensor die, the structures including at least one of a through-mold via (TMV), a redistribution layer, and a solder bump.
